(19) United States
(12) Patent Application Publication
(10) Pub. No.: US 2007/0138911 A1
(43) Pub. Date: Jun. 21, 2007

(54) TUNABLE ACOUSTIC DRIVER AND CAVITATION CHAMBER ASSEMBLY

(75) Inventors: Ross Alan Tessien, Nevada City, CA (US); Daniel A. Phillips, Grass Valley, CA (US)

Correspondence Address: PATENT LAW OFFICE OF DAVID G. BECK, P. O. BOX 1146, MILL VALLEY, CA, 94942, US

(73) Assignee: Impulse Devices Inc., Grass Valley, CA (US)

(21) Appl. No.: 11/305,571

(22) Filed: Dec. 16, 2005

(51) Int. Cl. H01L 41/08

(52) U.S. Cl. 310/328

(57) ABSTRACT

An acoustic driver assembly that is adjustably coupled to a cavitation chamber is provided. The cavitation chamber can be selected from any of a variety of cavitation chamber configurations including spherical, cylindrical, and rectangular chambers. The acoustic driver assembly includes a head mass, a tail mass, and at least one transducer. A portion of the head mass of the acoustic driver assembly passes through an acoustic driver port located within a portion of the cavitation chamber. The head mass is sealed to the inside of the acoustic driver port with at least one o-ring, static packing seal, or dynamic packing seal. The tail mass is either rigidly coupled to the cavitation chamber or non-rigidly coupled to the cavitation chamber. Compressible members can be used to further minimize the dampening effects associated with coupling the tail mass to the cavitation chamber.

### FIELD OF THE INVENTION

The present invention relates generally to sonoluminescence and, more particularly, to a system that allows the position of the driver assembly to be optimized for a particular cavitation chamber configuration.

### BACKGROUND OF THE INVENTION

Sonoluminescence is a well-known phenomena discovered in the 1930's in which light is generated when a liquid is cavitated. Although a variety of techniques for cavitating the liquid are known (e.g., spark discharge, laser pulse, flowing the liquid through a Venturi tube), one of the most common techniques is through the application of high intensity sound waves.

In essence, the cavitation process consists of three stages; bubble formation, growth and subsequent collapse. The bubble or bubbles cavitated during this process absorb the applied energy, for example sound energy, and then release the energy in the form of light emission during an extremely brief period of time. The intensity of the generated light depends on a variety of factors including the physical properties of the liquid (e.g., density, surface tension, vapor pressure, chemical structure, temperature, hydrostatic pressure, etc.) and the applied energy (e.g., sound wave amplitude, sound wave frequency, etc.).

Although it is generally recognized that during the collapse of a cavitating bubble extremely high temperature plasmas are developed, leading to the observed sonoluminescence effect, many aspects of the phenomena have not yet been characterized. As such, the phenomena is at the heart of a considerable amount of research as scientists attempt to not only completely characterize the phenomena (e.g., effects of pressure on the cavitating medium), but also its many applications (e.g., sonochemistry, chemical detoxification, ultrasonic cleaning, etc.).

Although acoustic drivers are commonly used to drive the cavitation process, there is little information about methods of coupling the acoustic energy to the cavitation chamber. For example, in an article entitled Ambient Pressure Effect on Single-Bubble Sonoluminescence by Dan et al. published in vol. 83, no. 9 of Physical Review Letters, the authors describe their study of the effects of ambient pressure on bubble dynamics and single bubble sonoluminescence. Although the authors describe their experimental apparatus in some detail, they only disclose that a piezoelectric transducer was used at the fundamental frequency of the chamber, not how the transducer couples its energy into the chamber.

U.S. Pat. No. 4,333,796 discloses a cavitation chamber that is generally cylindrical although the inventors note that other shapes, such as spherical, can also be used. As disclosed, the chamber is comprised of a refractory metal such as tungsten, titanium, molybdenum, rhenium or some alloy thereof and the cavitation medium is a liquid metal such as lithium or an alloy thereof. Surrounding the cavitation chamber is a housing which is purportedly used as a neutron and tritium shield. Projecting through both the outer housing and the cavitation chamber walls are a number of acoustic horns, each of the acoustic horns being coupled to a transducer which supplies the mechanical energy to the associated horn. The specification only discloses that the horns, through the use of flanges, are secured to the chamber/housing walls in such a way as to provide a seal and that the transducers are mounted to the outer ends of the horns.

U.S. Pat. No. 5,658,534 discloses a sonochemical apparatus consisting of a stainless steel tube about which ultrasonic transducers are affixed. The patent provides considerable detail as to the method of coupling the transducers to the tube. In particular, the patent discloses a transducer fixed to a cylindrical half-wavelength coupler by a stud, the coupler being clamped within a stainless steel collar welded to the outside of the sonochemical tube. The collars allow circulation of oil through the collar and an external heat exchanger. The abutting faces of the coupler and the transducer assembly are smooth and flat. The energy produced by the transducer passes through the coupler into the oil and then from the oil into the wall of the sonochemical tube.

U.S. Pat. No. 5,659,173 discloses a sonoluminescence system that uses a transparent spherical flask. The spherical flask is not described in detail, although the specification discloses that flasks of Pyrex®, Kontes®, and glass were used with sizes ranging from 10 milliliters to 5 liters. The drivers as well as a microphone piezoelectric were simply epoxied to the exterior surface of the chamber.

U.S. Pat. No. 5,858,104 discloses a shock wave chamber partially filled with a liquid. The remaining portion of the chamber is filled with gas which can be pressurized by a connected pressure source. Acoustic transducers are used to position an object within the chamber while another transducer delivers a compressional acoustic shock wave into the liquid. A flexible membrane separating the liquid from the gas reflects the compressional shock wave as a dilation wave focused on the location of the object about which a bubble is formed. The patent simply discloses that the transducers are mounted in the chamber walls without stating how the transducers are to be mounted.

U.S. Pat. No. 5,994,818 discloses a transducer assembly for use with tubular resonator cavity rather than a cavitation chamber. The assembly includes a piezoelectric transducer coupled to a cylindrical shaped transducer block. The transducer block is coupled via a central threaded bolt to a wave guide which, in turn, is coupled to the tubular resonator cavity. The transducer, transducer block, wave guide and resonator cavity are co-axial along a common central longitudinal axis. The outer surface of the end of the wave guide and the inner surface of the end of the resonator cavity are each threaded, thus allowing the wave guide to be threadably and rigidly coupled to the resonator cavity.

U.S. Pat. No. 6,361,747 discloses an acoustic cavitation reactor in which the reactor chamber is comprised of a flexible tube. The liquid to be treated circulates through the tube. Electroacoustic transducers are radially and uniformly distributed around the tube, each of the electroacoustic transducers having a prismatic bar shape. A film of lubricant is interposed between the transducer heads and the wall of the tube to help couple the acoustic energy into the tube.

U.S. Pat. No. 6,956,316 discloses an acoustic driver assembly for use with a spherical cavitation chamber. The surface of the driver's head mass that is coupled to the chamber has a spherical curvature greater than the spherical curvature of the external surface of the chamber, thus providing a ring of contact between the acoustic driver and the cavitation chamber. The area of the contact ring can be controlled, for example by chamfering a portion of the head mass such that the chamfered surface has the same curvature as the external surface of the chamber.

PCT Application No. US00/32092 discloses several driver assembly configurations for use with a solid cavitation reactor. The disclosed reactor system is comprised of a solid spherical reactor with multiple integral extensions surrounded by a high pressure enclosure. Individual driver assemblies are coupled to each of the reactor's integral extensions, the coupling means sealed to the reactor's enclosure in order to maintain the high pressure characteristics of the enclosure.

### SUMMARY OF THE INVENTION

The present invention provides an acoustic driver assembly that is adjustably coupled to a cavitation chamber, the cavitation chamber selected from any of a variety of cavitation chamber configurations including spherical, cylindrical, and rectangular chambers. The acoustic driver assembly includes a head mass, a tail mass, and at least one transducer. Preferably the transducer is a piezoelectric transducer, and more preferably a pair of piezoelectric transducers. The tail mass and the at least one transducer are preferably coupled to the head mass with a bolt or an all thread and nut assembly. In at least one embodiment the head mass is shaped.

A portion of the head mass of the acoustic driver assembly passes through an acoustic driver port located within a portion (e.g., end cap, wall, etc.) of the cavitation chamber. The head mass is sealed to the inside of the acoustic driver port with at least one o-ring, static packing seal, or dynamic packing seal.

In one embodiment of the invention, the tail mass of the acoustic driver assembly is coupled to the cavitation chamber, for example using multiple threaded means (e.g., all threads) and corresponding nuts. The tail mass is rigidly coupled to the cavitation chamber by capturing the tail mass between pairs of nuts which correspond to each of the multiple threaded means. Alternately, the tail mass is non-rigidly coupled to the cavitation chamber, for example by only using the threaded means and nut combinations to position the tail mass, not lock it into place. Alternately, compressible members are interposed between the nuts and the exterior surfaces of the tail mass, thus minimizing the dampening effects associated with coupling the tail mass to the cavitation chamber.

In another embodiment of the invention, the tail mass of the acoustic driver assembly is located on a driver assembly positioning plate, the positioning plate being rigidly coupled to the cavitation chamber. In order to minimize the dampening effects of the cavitation chamber, a compressible member can be interposed between the tail mass and the driver assembly positioning plate.

A further understanding of the nature and advantages of the present invention may be realized by reference to the remaining portions of the specification and the drawings.

### BRIEF DESCRIPTION OF THE DRAWINGS

FIG. 1 is a perspective view of a driver assembly in accordance with the prior art;

FIG. 2 is a cross-sectional view of the driver assembly shown in FIG. 1, attached to the wall of a cavitation chamber;

FIG. 3 is an illustration of an acoustic driver coupled to a horn, the horn passing through the cavitation chamber wall in accordance with the prior art;

FIG. 4 is an illustration of an acoustic driver and cavitation chamber assembly in accordance with the invention;

FIG. 5 is an illustration of an embodiment of the invention similar to that shown in FIG. 4, except for the use of a different driver assembly mounting arrangement;

FIG. 6 is an illustration of an embodiment of the invention similar to that shown in FIG. 4, except for the use of compressible members interposed between the driver's tail mass and the tail mass mounting nuts;

FIG. 7 is an illustration of an embodiment of the invention similar to that shown in FIG. 4, except for the use of a separate driver mounting plate;

FIG. 8 is an illustration of an embodiment of the invention similar to that shown in FIG. 7, except for the inclusion of a compressible member between the driver and the driver mounting plate;

FIG. 9 is an illustration of an embodiment of the invention similar to that shown in FIG. 4, except for the shape of the head mass; and

FIG. 10 is an illustration of a spherical cavitation chamber utilizing two driver assemblies mounted in accordance with the invention.

### DESCRIPTION OF THE SPECIFIC EMBODIMENTS

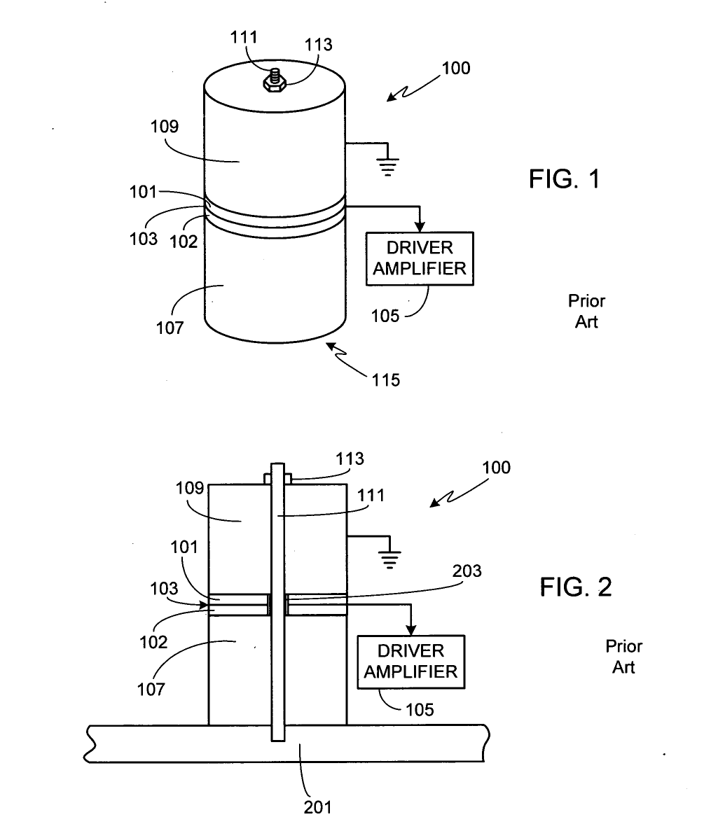

FIG. 1 is a perspective view of a driver assembly 100 in accordance with the prior art. FIG. 2 is a cross-sectional view of the same driver assembly coupled to a wall portion 201 of a cavitation chamber.

Piezoelectric transducers are typically used in driver 100 although magnetostrictive transducers can also be used when lower frequencies are desired. A combination of piezoelectric and magnetostrictive transducers can also be used, for example as a means of providing greater frequency bandwidth.

Although driver assembly 100 can use a single piezoelectric transducer, preferably assembly 100 uses a pair of piezoelectric transducer rings 101 and 102 poled in opposite directions. By using a pair of transducers in which the adjacent surfaces of the two crystals have the same polarity, potential grounding problems are minimized. Suitable piezoelectric transducers are fabricated by Channel Industries of Santa Barbara, Calif. An electrode disc 103 is located between transducer rings 101 and 102 which, during operation, is coupled to the driver power amplifier 105.

The transducer pair is sandwiched between a head mass 107 and a tail mass 109. Head mass 107 and tail mass 109 can be fabricated from the same material and be of equal mass. Alternately head mass 107 and tail mass 109 can be fabricated from different materials. In yet other alternatives, head mass 107 and tail mass 109 can have different masses and/or different mass diameters and/or different mass lengths. For example tail mass 109 can be much larger than head mass 107.

Typically driver assembly 100 is assembled about a centrally located all-thread 111 which is screwed directly into the wall 201 of the cavitation chamber. A nut 113 holds the assembly together. If all-thread 111 does not pass through the entire chamber wall as shown, the internal surface of the cavitation chamber remains smooth, thus insuring that there are neither gas nor liquid leaks at the point of driver attachment. It is understood that all-thread 111 and nut 113 can be replaced with a bolt or other means of attachment. An insulating sleeve 203 isolates all-thread 111, preventing it from shorting electrode 103. Preferably insulating sleeve 203 is fabricated from Teflon.

As previously noted, attaching the driver assembly to the outside of the cavitation chamber is advantageous as it eliminates a potential source of gas and fluid leaks, assuming that the means used to couple the driver to the chamber does not extend through the chamber wall. A disadvantage, however, of this approach is that the energy produced by the driver is dampened by the chamber wall, the degree of dampening being directly proportional to the thickness of the wall. Accordingly even though thick walls can handle higher pressures and are generally better from a fabrication and assembly point of view, for example providing a convenient mounting location for drivers, such walls can significantly decrease the coupling efficiency between the driver and the cavitation fluid within the chamber.

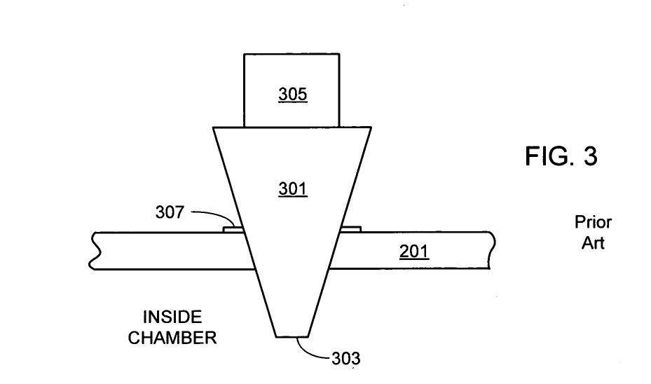

One method of overcoming the disadvantages of an externally mounted driver assembly is to couple the driver to a horn that passes directly through the chamber wall as illustrated in FIG. 3. As shown, horn 301 passes through cavitation chamber wall 201, thus providing a surface (e.g., horn end surface 303) that is in direct contact with the cavitation fluid contained within the chamber. An acoustic driver assembly 305, such as previously illustrated assembly 100, is coupled to a portion of horn 301 which is outside of the cavitation chamber. A flange 307 seals horn 301 to chamber wall 201.

Optimizing the cavitation system's operation is desirable in order to achieve high energy density cavitation induced implosions within the cavitation fluid. Although the use of a horn that passes through the cavitation chamber wall can dramatically improve coupling efficiency between the driver and the cavitation fluid, it still does not allow for the complete optimization of the cavitation process. As one of the factors that directly impacts the energy density is chamber resonance, the inventors have found that by allowing the position of the head mass of the driver assembly to be adjusted within the cavitation chamber, further system optimization can be achieved through system tuning. This feature is particularly useful if the volume of the cavitation fluid within the cavitation chamber is not constant, for example due to the chamber not being completely filled with fluid during operation.

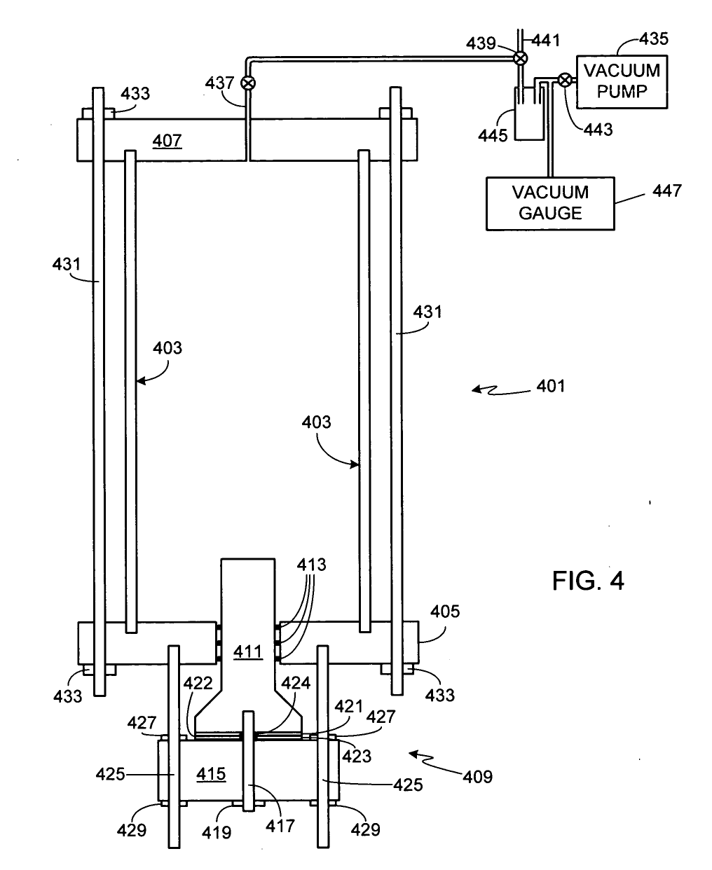

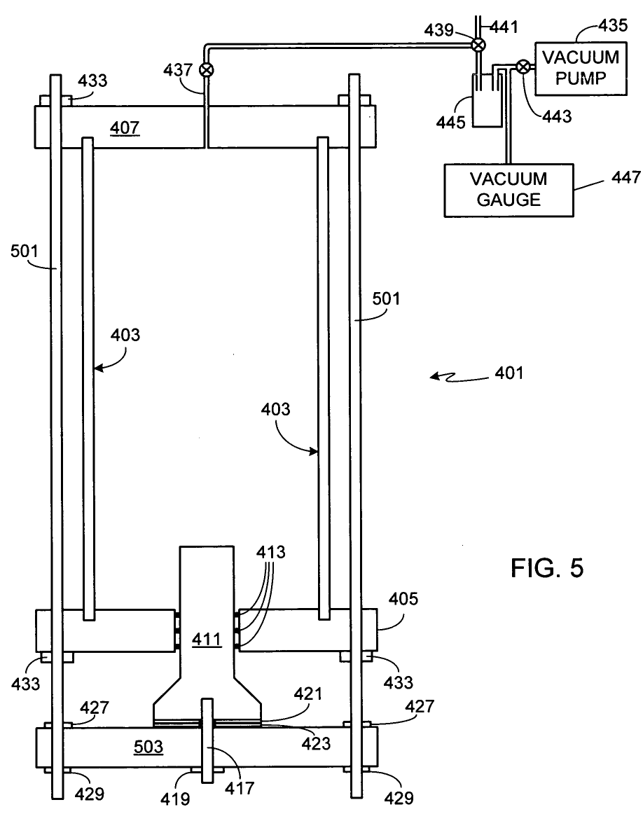

FIG. 4 is an illustration of a cavitation chamber and driver assembly according to the invention. In this embodiment, chamber 401 is comprised of a cylindrical wall portion 403 and a pair of end caps 405 and 407. Coupled to end cap 405 is an adjustable driver assembly 409. Head mass 411 of driver assembly 409 passes through an acoustic driver port located in end cap 405 and is non-permanently sealed to the chamber (i.e., end cap 405) with at least one, and preferably multiple, o-rings 413. As the purpose of o-rings 413 is to provide a gas and liquid seal while still allowing the location of driver assembly 409 within the chamber to be varied, it will be appreciated that the invention is not limited to a particular type of seal. Depending upon the intended cavitation fluid as well as the desired operating pressure, a variety of types of seals can be used, alone or in combination, to provide the desired seal. For example, in addition to o-rings, the invention can utilize static packing seals such as gaskets and dynamic packing seals such as flanges, rings, and adjustable soft packings.

In the embodiment illustrated in FIG. 4, head mass 411 is coupled to tail mass 415 using either an all thread 417 and a nut 419 as shown, or with a bolt (not shown). In between head mass 411 and tail mass 415 is a transducer, preferably a piezoelectric transducer, and more preferably a pair of piezoelectric transducers 421/423 as previously described relative to FIGS. 1 and 2. Preferably an insulating sleeve 424 isolates transducers 421/423 and the transducer electrode 422 from threaded means 417.

In order to maintain driver assembly 409 in the desired position relative to chamber 401 and end cap 405, in this embodiment multiple threaded means 425 (e.g., all threads) pass through tail mass 415 and are threaded into end cap 405. In this embodiment typically at least three threaded means 425 are used to hold driver assembly 409 in place. Once driver assembly 409 is positioned as desired, a pair of nuts 427/429 holds tail mass 415, and thus assembly 409, in position.

Although the chamber shown in the embodiment of FIG. 4 is a cylindrical chamber, it should be appreciated that the invention is not limited to a particular chamber configuration. Particular configurations are typically selected to accommodate a specific cavitation process and its corresponding process parameters (e.g., cavitation fluid, pressure, temperature, reactants, etc.). Examples of other configurations include spherical chambers, hourglass-shaped chambers, conical chambers, cubical chambers, rectangular chambers, irregularly-shaped chambers, etc. One method of fabricating a suitable spherical chamber is described in detail in co-pending U.S. patent application Ser. No. 10/925,070, filed Aug. 23, 2004, entitled Method of Fabricating a Spherical Cavitation Chamber, the entire disclosure of which is incorporated herein for any and all purposes. Examples of hourglass-shaped chambers are provided in co-pending U.S. patent application Ser. Nos. 11/140,175, filed May 27, 2005, entitled Hourglass-Shaped Cavitation Chamber, and 11/149,791, filed Jun. 9, 2005, entitled Hourglass-Shaped Cavitation Chamber with Spherical Lobes, the entire disclosures of which are incorporated herein for any and all purposes.

The cavitation chamber of the invention can be fabricated from any of a variety of materials, or any combination of materials, although the surface through which the cavitation driver (or drivers) passes is preferably fabricated from a machinable material, thus providing a simple means of attaching the driver assembly to the chamber, e.g., via threaded means as shown in FIG. 4. Other considerations for material selection are the desired operating pressure and temperature of the chamber and system. In addition, preferably the material or materials selected for the cavitation chamber are relatively corrosion resistant to the intended cavitation fluid, thus allowing the chamber to be used repeatedly.

The materials used to fabricate the cavitation chamber can be selected to simplify viewing of the sonoluminescence phenomena, for example utilizing a transparent material such as glass, borosilicate glass, or quartz glass (e.g., Pyrex®). Alternately the cavitation chamber can be fabricated from a more robust material (e.g., 17-4 precipitation hardened stainless steel) and one which is preferably machinable, thus simplifying fabrication. Alternately a portion of the chamber can be fabricated from one material while other portions of the chamber can be fabricated from one or more different materials. For example, in the preferred embodiment illustrated in FIG. 4, cylindrical portion 403 is fabricated from a transparent material (e.g., glass) while end caps 405 and 407 are fabricated from a metal (e.g., aluminum), the assembly being held together with multiple all-threads 431 and nuts 433.

The selected dimensions of the cavitation chamber depend on many factors, including the cost of the cavitation fluid, chamber fabrication issues, operating temperature and frequency, sound speed, and the cavitation driver capabilities. In general, small chambers are preferred for situations in which it is desirable to limit the amount of the cavitation medium or in which driver input energy is limited while large chambers (e.g., 10 inches or greater) are preferred as a means of simplifying experimental set-up and event observation or when high energy reactions or large numbers of low energy reactions are being driven within the chamber. Thick chamber walls are preferred in order to accommodate high pressures.

In order to efficiently achieve high energy density (e.g., temperature) cavitation induced implosions within the cavitation fluid within the cavitation chamber, preferably the cavitation fluid is first adequately degassed of unwanted contaminants. Without sufficient degassing, gas within the cavitation fluid will impede the cavitation process by decreasing the maximum rate of collapse as well as the peak stagnation pressure and temperature of the plasma within the cavitating bubbles. It will be understood that the term “gas”, as used herein, refers to any of a variety of gases that are trapped within the cavitation fluid, these gases typically reflecting the gases contained within air (e.g., oxygen, nitrogen, argon, etc.). In contrast, “vapor” only refers to molecules of the cavitation fluid that are in the gaseous phase.

The present invention is not limited to a particular degassing technique. In the preferred embodiment, degassing is performed with a vacuum pump 435 that is coupled to chamber 401 via conduit 437. In an alternate embodiment, degassing can be performed within a separate degassing reservoir in which the cavitation fluid is degassed prior to filling the cavitation chamber. In yet another alternate embodiment, the cavitation fluid can be degassed initially outside of chamber 401 and then again within chamber 401.

In the embodiment illustrated in FIG. 4, a three-way valve 439 allows the system to be coupled to the ambient atmosphere via conduit 441 or to vacuum pump 435. It will be appreciated that three-way valve 439 can be replaced with a pair of two-way valves (not shown). Valve 443 provides a means for isolating the system from pump 435. Preferably a trap 445 is used to insure that cavitation fluid is not drawn into vacuum pump 435 or vacuum gauge 447. Preferably trap 445 is cooled so that any cavitation medium entering the trap condenses or solidifies. Vacuum gauge 447 is used to provide an accurate assessment of the system pressure. If the cavitation system becomes pressurized, prior to re-coupling the system to either vacuum gauge 447 or vacuum pump 435 the cavitation system pressure is bled down to an acceptable level using three-way valve 439.

A cavitation fluid filling system, not shown, is coupled to chamber 401 and used to fill the chamber to the desired level. It will be appreciated that the operating level for a particular cavitation chamber is based on obtaining the most efficient cavitation action. For example, while a spherical chamber may be most efficiently operated when it is completely full, a vertically aligned cylindrical chamber (e.g., the chamber shown in FIG. 4) may operate most efficiently when it is not completely full, thus providing a free cavitation liquid surface at the top of the chamber. The filling system may utilize a simple fill tube (e.g., conduit 441), a separate fluid reservoir, or other filling means. Regardless of the method used to fill the cavitation chamber, preferably the system is evacuated prior to filling, thus causing the cavitation medium to be drawn into the system (i.e., utilizing ambient air pressure to provide the pressure to fill the system).

Although not required, the filling system may include a circulatory system, such as that described in co-pending U.S. patent application Ser. No. 11/001,720, filed Dec. 1, 2004, entitled Cavitation Fluid Circulatory System for a Cavitation Chamber, the disclosure of which is incorporated herein for any and all purposes. Other components that may or may not be coupled to the cavitation fluid filling and/or circulatory system include bubble traps, cavitation fluid filters, and heat exchange systems. Further descriptions of some of these variations are provided in co-pending U.S. patent application Ser. No. 10/961,353, filed Oct. 7, 2004, entitled Heat Exchange System for a Cavitation Chamber, the disclosure of which is incorporated herein for any and all purposes.

It will be appreciated that the invention lies in the ability to readily tune the system by varying the depth that the acoustic driver assembly penetrates the cavitation chamber. Accordingly, the shape of the driver assembly, the means used to adjust the depth of penetration, and the configuration of the cavitation chamber to which the driver (or drivers) is attached is not critical to the implementation of the invention. For example, FIG. 5 is an illustration of an embodiment similar to that shown in FIG. 4 except that all threads 431, which are used to hold chamber cylindrical portion 403 and end caps 405 and 407 together, are replaced with longer all threads 501. Additionally, tail mass 503 of the driver assembly is large enough that all threads 501 can be used to hold the driver assembly in place, as shown.

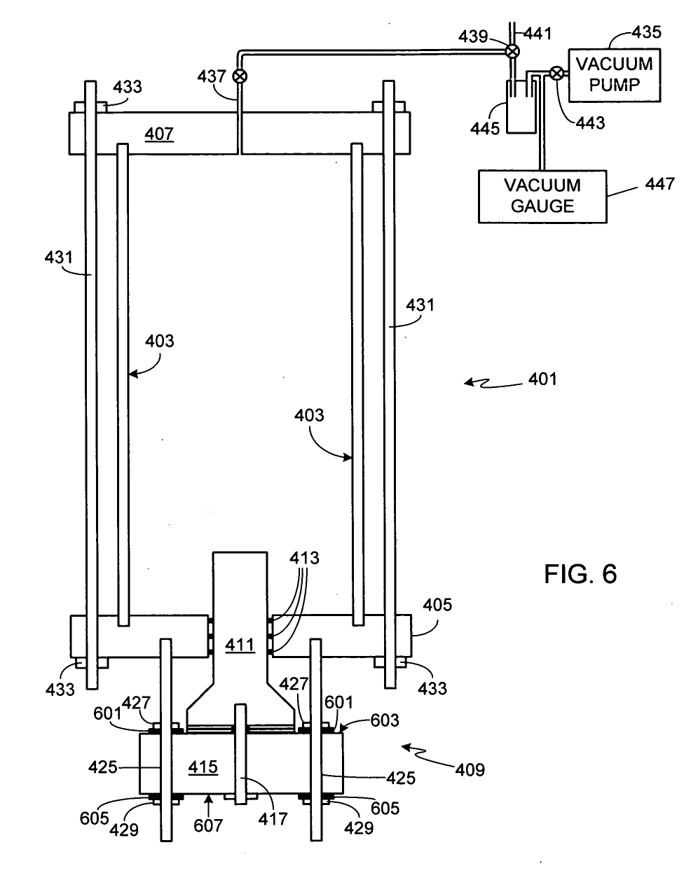

An advantage of the present invention, in addition to providing a driver assembly in which the amount that the head mass extends into the cavitation chamber is adjustable, is that it helps to reduce the degree to which the energy of the driver is dampened by the chamber. This effect is a result of using a flexible seal between the head mass and the chamber (e.g., o-rings 413) rather than rigidly coupling the two together (e.g., flange 307 in FIG. 3). FIG. 6 illustrates an embodiment in which this attribute of the invention is enhanced.

The embodiment of the invention shown in FIG. 6 is quite similar to that shown in FIG. 4. In this embodiment, however, compressible members 601 are interposed between driver assembly locking nuts 427 and surface 603 of tail mass 415. Similarly, compressible members 605 are interposed between driver assembly locking nuts 429 and surface 607 of tail mass 415. Compressible members 601 and 605 further decouple the driver assembly from the chamber, thus lessening the dampening effects of the chamber, while still providing an effective means of positioning the head mass relative to the chamber. Members 601 and 605 can be made from any of a variety of elastomers (e.g., rubber, neoprene, silicon, high density foam, etc.). Compressible members 601 and 605 can also be used with other embodiments, such as the one shown in FIG. 5.

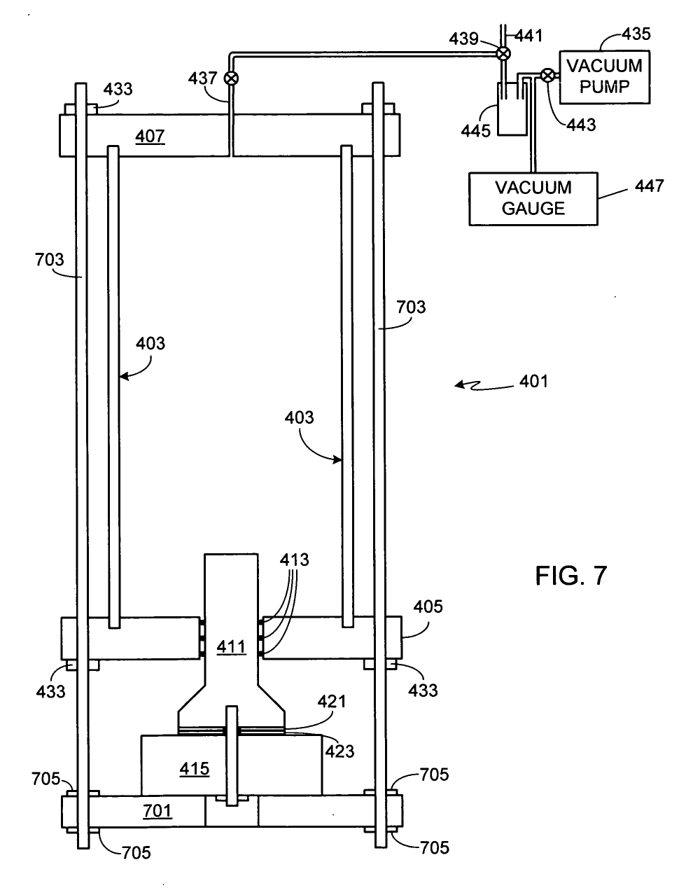

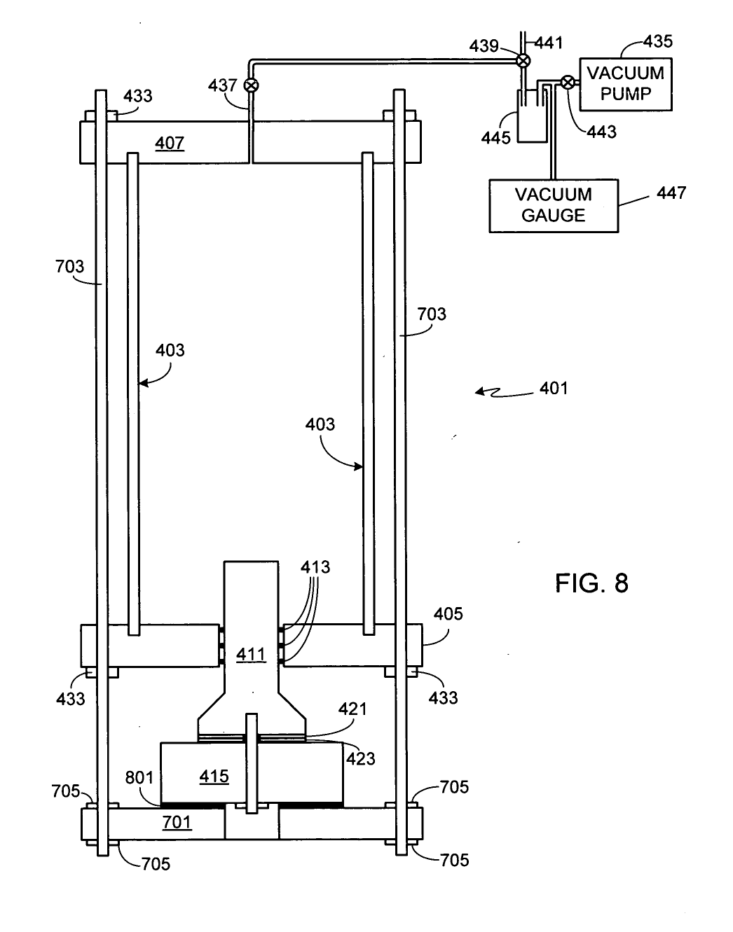

Although the driver assembly can be held in place as previously shown, in an alternate embodiment the weight of the driver assembly helps hold it in place. For example, by removing nuts 427 from the embodiments shown in FIGS. 4 and 6, the weight of the driver assembly holds it against nuts 429 (i.e., FIG. 4) or nuts 429 and compressible members 605 (i.e., FIG. 6). FIG. 7 shows an alternate embodiment in which driver assembly 409 rests on top of a driver positioning plate 701, plate 701 rigidly attached to all threads 703 with nuts 705. If desired, a compressible member 801 can be interposed between tail mass 415 and plate 701 as shown in FIG. 8. Of course it will be appreciated that using gravity and the weight of the driver assembly to hold it in place (e.g., as shown in FIGS. 7 and 8) works best if the driver assembly is positioned at the bottom of the chamber as shown in the embodiments of FIGS. 7 and 8. If the driver assembly is otherwise positioned, for example at the top of the chamber, gravity and the weight of the driver assembly will typically cause the driver to shift out of the desired position. In such applications the driver assembly must be locked into place as previously described relative to FIGS. 4-6.

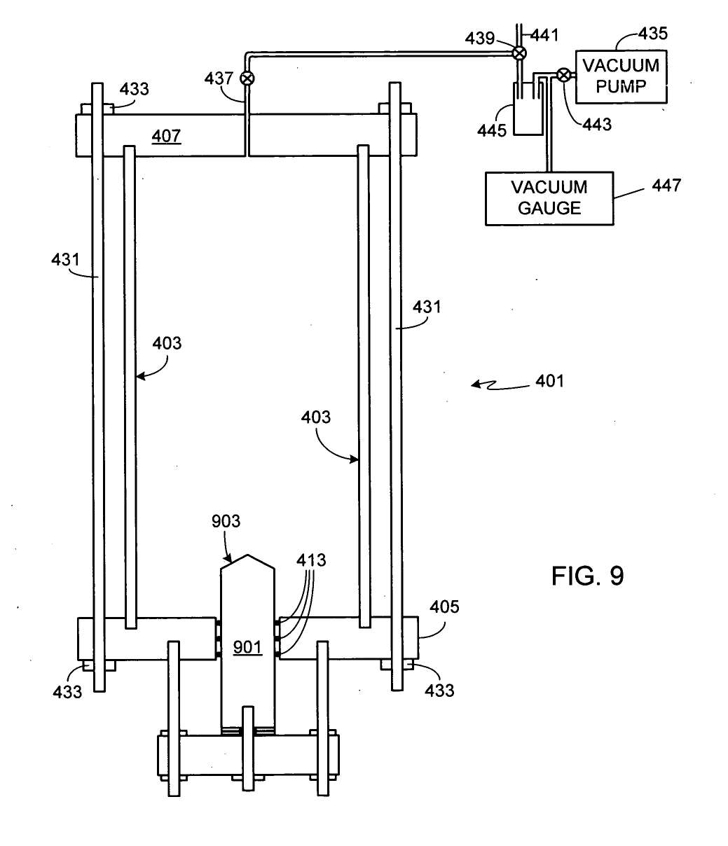

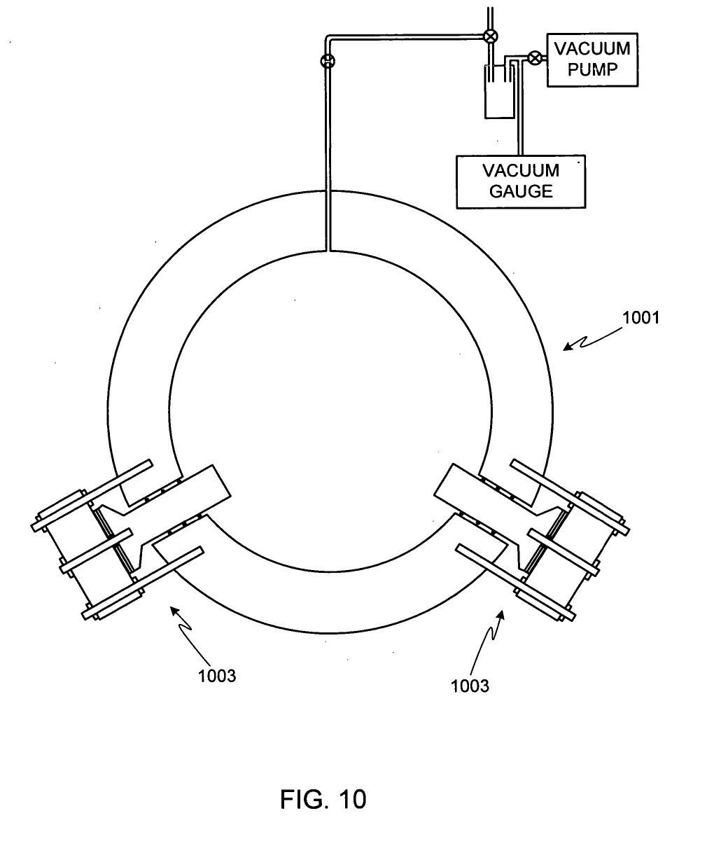

As previously noted, the present application is not limited to specific driver configurations. For example, the embodiment illustrated in FIG. 9 uses a cylindrically-shaped head mass 901 with a conically-shaped head mass end surface 903. Additionally, and also as previously noted, other chamber configurations can be used with the invention. The embodiment illustrated in FIG. 10 includes a spherical cavitation chamber 1001 with a pair of driver assemblies 1003 coupled to the chamber as described above relative to other embodiments of the invention.

Although not required by the invention, preferably void filling material is included between some or all adjacent pairs of surfaces of the driver assembly, thereby improving the overall coupling efficiency and operation of the driver. Suitable void filling material should be sufficiently compressible to fill the voids or surface imperfections of the adjacent surfaces while not being so compressible as to overly dampen the acoustic energy supplied by the transducers. Preferably the void filling material is a high viscosity grease, although wax, very soft metals (e.g., solder), or other materials can be used.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A cavitation system, comprising:
a cavitation chamber, said cavitation chamber further comprising an acoustic driver port;
an acoustic driver assembly, comprising:
at least one transducer;
a tail mass adjacent to a first side of said at least one transducer;
a head mass with a first end surface adjacent to a second side of said at least one transducer, wherein at least a portion of said head mass passes at least partially through said acoustic driver port; and
means for assembling said acoustic driver assembly;
means for positioning said head mass within said acoustic driver port, wherein said positioning means is adjustable between at least a first position and a second position; and
means for non-permanently sealing said head mass within said acoustic driver port.

2. The cavitation system of claim 1, wherein said assembling means further comprises a centrally located threaded means coupling said tail mass and said at least one transducer to said head mass.

3. The cavitation system of claim 2, wherein said assembling means further comprises a threaded nut corresponding to said centrally located threaded means, wherein said threaded nut compresses said tail mass and said at least one transducer against said head mass.

4. The cavitation system of claim 2, further comprising an insulating sleeve surrounding at least a portion of said centrally located threaded means, wherein said insulating sleeve is interposed between said centrally located threaded means and said at least one transducer.

5. The cavitation system of claim 1, wherein said positioning means further comprises:
a plurality of threaded means, wherein each of said threaded means is threadably coupled to a portion of said cavitation chamber, and wherein each of said threaded means passes through a portion of said tail mass; and
a plurality of nuts corresponding to said plurality of threaded means, wherein said tail mass has a first exterior surface and a second exterior surface, wherein a portion of said first exterior surface of said tail mass is adjacent to said at least one transducer, wherein said second exterior surface of said tail mass is located further from said cavitation chamber than said first exterior surface of said tail mass, and wherein said plurality of nuts are located adjacent to said second exterior surface of said tail mass.

6. The cavitation system of claim 5, wherein said positioning means further comprises a plurality of compressible members interposed between said second exterior surface of said tail mass and said plurality of nuts.

7. The cavitation system of claim 5, wherein said positioning means further comprises a second plurality of nuts corresponding to said plurality of threaded means, wherein said second plurality of nuts are located adjacent to said first exterior surface of said tail mass.

8. The cavitation system of claim 7, wherein said positioning means further comprises a first plurality of compressible members interposed between said second exterior surface of said tail mass and said plurality of nuts, and a second plurality of compressible members interposed between said first exterior surface of said tail mass and said second plurality of nuts.

9. The cavitation system of claim 1, wherein said cavitation chamber further comprises:
a cylindrical section;
a first end cap;
a second end cap; and
cavitation chamber assembly means comprising a plurality of threaded means, a first plurality of nuts corresponding to said plurality of threaded means and located adjacent to an exterior surface of said first end cap, and a second plurality of nuts corresponding to said plurality of threaded means and located adjacent to an exterior surface of said second end cap.

10. The cavitation system of claim 9, wherein said positioning means further comprises a third plurality of nuts corresponding to said plurality of threaded means, wherein each of said threaded means passes through a portion of said tail mass, wherein said tail mass has a first exterior surface and a second exterior surface, wherein a portion of said first exterior surface of said tail mass is adjacent to said at least one transducer, wherein said second exterior surface of said tail mass is located further from said cavitation chamber than said first exterior surface of said tail mass, and wherein said third plurality of nuts are located adjacent to said second exterior surface of said tail mass.

11. The cavitation system of claim 10, wherein said positioning means further comprises a plurality of compressible members interposed between said second exterior surface of said tail mass and said third plurality of nuts.

12. The cavitation system of claim 10, wherein said positioning means further comprises a fourth plurality of nuts corresponding to said plurality of threaded means, wherein said fourth plurality of nuts are located adjacent to said first exterior surface of said tail mass.

13. The cavitation system of claim 12, wherein said positioning means further comprises a first plurality of compressible members interposed between said second exterior surface of said tail mass and said third plurality of nuts, and a second plurality of compressible members interposed between said first exterior surface of said tail mass and said fourth plurality of nuts.

14. The cavitation system of claim 9, further comprising:
a driver assembly positioning plate, wherein each of said threaded means passes through a portion of said driver assembly positioning plate, wherein at least a portion of an exterior surface of said tail mass rests on at least a portion of a first exterior surface of said driver assembly positioning plate;
a third plurality of nuts corresponding to said plurality of threaded means, wherein said third plurality of nuts are located adjacent to said first exterior surface of said driver assembly positioning plate;
a fourth plurality of nuts corresponding to said plurality of threaded means, wherein said fourth plurality of nuts are located adjacent to a second exterior surface of said driver assembly positioning plate.

15. The cavitation system of claim 14, further comprising a compressible member interposed between said portion of said exterior surface of said tail mass and said portion of said first exterior surface of said driver assembly positioning plate.

16. The cavitation system of claim 1, said sealing means comprising at least one o-ring.

17. The cavitation system of claim 1, said sealing means comprising at least one static packing seal.

18. The cavitation system of claim 1, said sealing means comprising at least one dynamic packing seal.

19. The cavitation system of claim 1, wherein a second end surface of said head mass is shaped.

20. The cavitation system of claim 1, wherein said at least one transducer is comprised of a piezoelectric transducer.

21. The cavitation system of claim 1, wherein said at least one transducer is comprised of a first piezoelectric transducer and a second piezoelectric transducer, wherein adjacent surfaces of said first and second piezoelectric transducers have the same polarity.

22. The cavitation system of claim 21, further comprising an electrode interposed between said adjacent surfaces of said first and second piezoelectric transducers.
